(19) United States
(12) Patent Application Publication
(10) Pub. No.: US 2026/0314319 A1
(43) Pub. Date: Oct. 8, 2026

(54) STRIKER FOR WAFER BONDING

(71) Applicant: Tokyo Electron Limited, Tokyo (JP)

(72) Inventors: Christopher Michael Netzband, Albany, NY (US); Ilseok Son, Albany, NY (US)

(21) Appl. No.: 19/170,728

(22) Filed: Apr. 4, 2025

(51) Int. Cl. H10P 72/72; H10D 88/00; H10P 72/50

(52) U.S. Cl. CPC H10P 72/722; H10D 88/01; H10P 72/50

(57) ABSTRACT

A method for bonding wafers includes aligning a first wafer with a second wafer to form a gap separating the first wafer from the second wafer, the first wafer being held with a first wafer holder and the second wafer being held with a second wafer holder, the second wafer holder including a plurality of chucking zones including a first set of chucking zones and a second set of chucking zones. The method further includes holding a surface of the second wafer with a striker, and releasing the first set of chucking zones while holding the second wafer with the striker. And the method further includes, after releasing the first set of chucking zones, pushing the second wafer into the first wafer while holding the second wafer with the striker, and releasing the second set of chucking zones to form a bonded wafer.

### TECHNICAL FIELD

The present invention relates generally to a system and method for semiconductor manufacturing, and, in particular embodiments, to a system and method for bonding wafers using a striker in a wafer bonding system.

### BACKGROUND

Wafer-to-wafer bonding is a common process in semiconductor manufacturing that desires precise control to achieve high-quality bonds while minimizing distortion. Conventional wafer bonding processes typically involve holding a second wafer above a first wafer, releasing the center portion of the second wafer from a wafer holder, and then initiating contact between the wafers using a mechanical striker pin that relies on gravitational force for operation.

### SUMMARY

In accordance with an embodiment of this disclosure, a method for bonding wafers includes aligning a first wafer with a second wafer to form a gap separating the first wafer from the second wafer, the first wafer being held with a first wafer holder and the second wafer being held with a second wafer holder, the second wafer holder including a plurality of chucking zones, the plurality of chucking zones including a first set of chucking zones and a second set of chucking zones. The method further includes holding a surface of the second wafer with a striker, the first set of chucking zones being located nearer to the striker than the second set of chucking zones, and releasing the first set of chucking zones while holding the second wafer with the striker. And the method further includes, after releasing the first set of chucking zones, pushing the second wafer into the first wafer using the striker while holding the second wafer with the striker, and releasing the second set of chucking zones to form a bonded wafer.

In accordance with another embodiment of this disclosure, a striker for bonding wafers includes a first chucking zone, and a second chucking zone.

And in accordance with yet another embodiment of this disclosure, a system for bonding wafers includes a bonding chamber including a second wafer holder, a first wafer holder, and a striker, the second wafer holder including a plurality of chucking zones, the striker including a first chucking zone and a second chucking zone. And the system further includes a controller coupled to the bonding chamber, the first wafer holder, the second wafer holder, the striker, and a memory storing instructions to be executed in the controller. The instructions when executed enable the controller to align a first wafer with a second wafer to form a gap separating the first wafer from the second wafer, the first wafer being held with the first wafer holder and the second wafer being held with the second wafer holder, the plurality of chucking zones including a first set of chucking zones and a second set of chucking zones, hold a surface of the second wafer with the striker, the first set of chucking zones being located nearer to the striker than the second set of chucking zones, release the first set of chucking zones of the second wafer holder while holding the second wafer with the striker, after releasing the first set of chucking zones, push the second wafer into the first wafer using the striker while holding the second wafer with the striker, and release the second set of chucking zones of the second wafer holder to form a bonded wafer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1H illustrate wafers during various steps of a wafer bonding method in accordance with an embodiment of this disclosure;

FIGS. 2A-2C illustrate schematic diagrams of strikers which may be used in the wafer bonding method of FIGS. 1A-1H in accordance with embodiments of this disclosure;

FIG. 3 illustrates a striker of FIGS. 2A-2C during the wafer bonding method of FIGS. 1A-1H in accordance with an embodiment of this disclosure;

FIG. 4 is a flowchart illustrating a wafer bonding method in accordance with an embodiment of this disclosure;

FIGS. 5A-5B are schematic diagrams of a wafer bonding apparatus and a wafer bonding system capable of implementing the wafer bonding method of FIGS. 1A-1H in accordance with an embodiment of this disclosure;

FIG. 6 illustrates a schematic diagram of a first wafer holder and a second wafer holder which may be used in the wafer bonding system of FIGS. 5A-5B in accordance with an embodiment of this disclosure; and

FIG. 7 is a flowchart illustrating a wafer bonding method in accordance with an embodiment of this disclosure.

### DETAILED DESCRIPTION OF ILLUSTRATIVE EMBODIMENTS

During wafer-to-wafer bonding, the initiation of the bond using conventional mechanical strikers can lead to uncorrectable distortions, particularly in the center region of the wafers. Current bonding processes rely on dropping the center of the wafer followed by releasing a striker pin, creating a period between center vacuum release and complete wafer bonding where both wafer and striker are moving ending with an impact on the back of the wafer. The center distortions created during this process produce a signature pattern that becomes challenging to eliminate during scanner correction when depositing subsequent device layers. While reducing the gap height between wafers could potentially improve these distortions, this approach cannot be properly explored because the increased pressure to overcome the thicker air cushion would amplify striker-related distortions, which are more challenging to address through lithography compared to other distortion types.

The disclosed apparatus employs an electrostatic-enabled or a vacuum-enabled striker that holds the wafer center before vacuum release and pushes the wafer into another wafer to overcome an initiation distance (or air gap) between the wafers, maintaining the hold and maintaining control throughout the bonding process. By utilizing technology similar to an electrostatic chuck or a vacuum chuck, the striker can securely grip the wafer and eliminate sharp impacts during the striking process, improving control and repeatability. The striker can apply precisely modulated pressure without physical impact, allowing for finer control than traditional mechanical striker bonding methods. This approach enables full control of the wafer between the time center vacuum is released and wafer bonding is complete, allowing for slow, uniform lowering until bond initiation occurs. The electrostatic configuration and the vacuum configuration also accommodate scenarios where the wafer is convex or the lower wafer holder is bowed, as they can maintain good alignment even when all upper wafer vacuum is released during the lowering process.

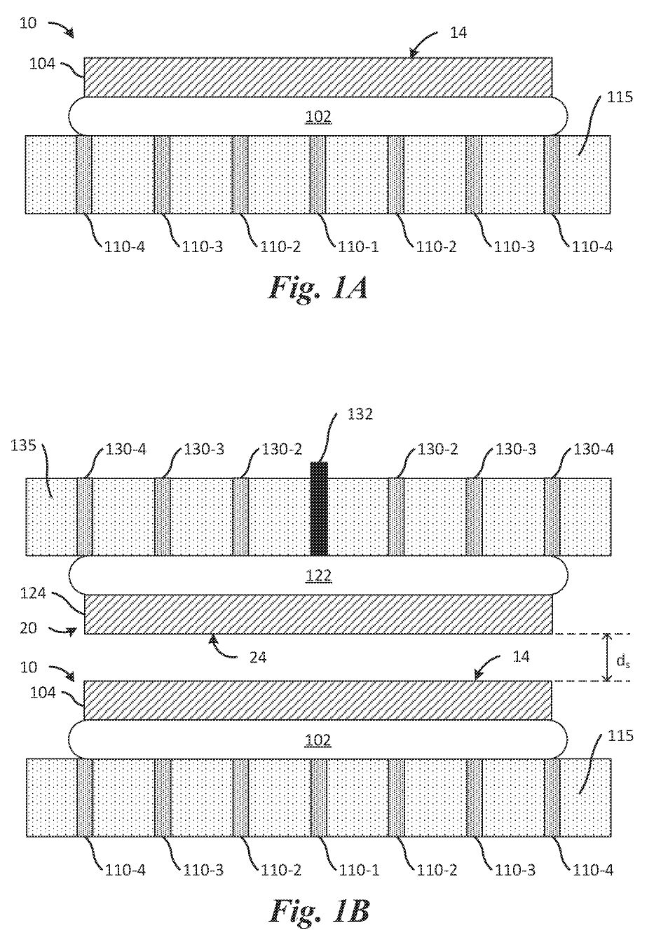

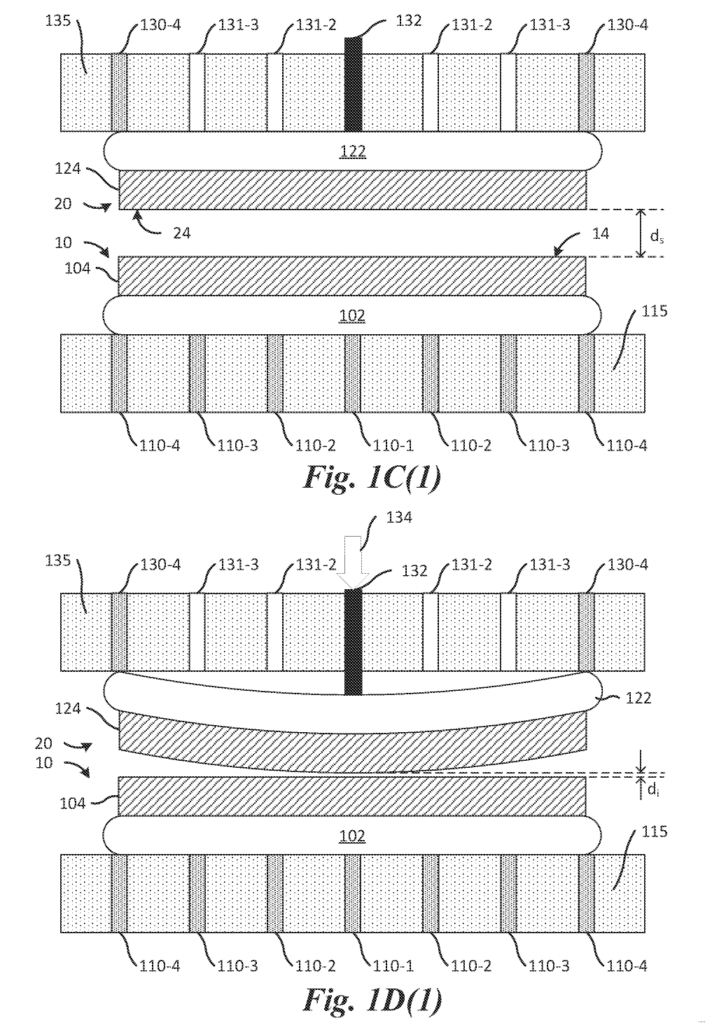

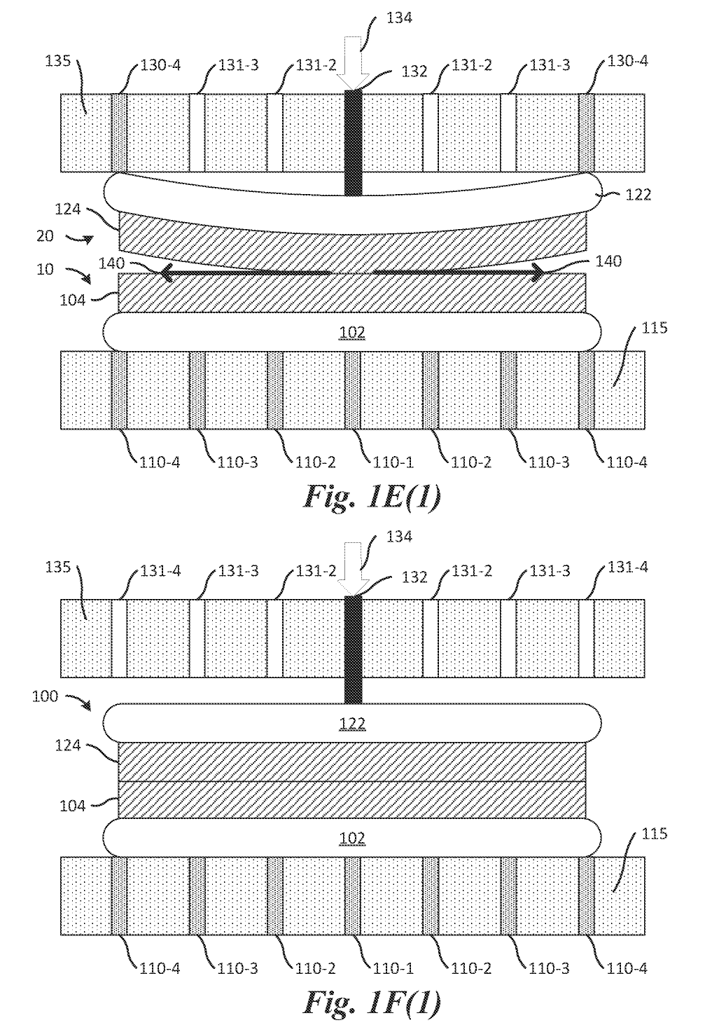

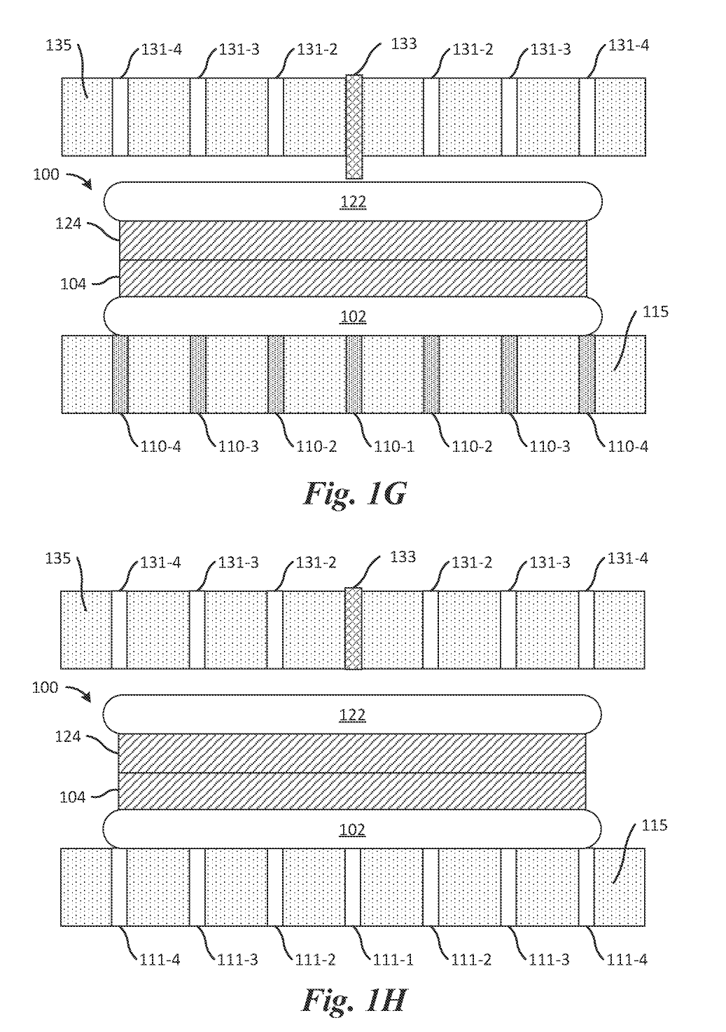

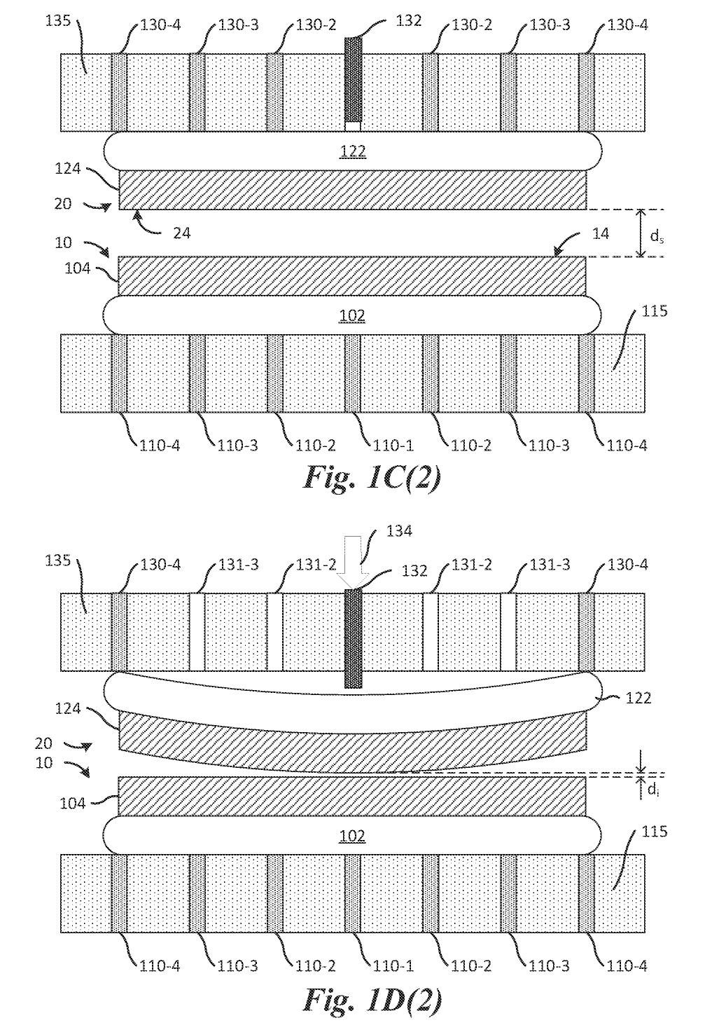

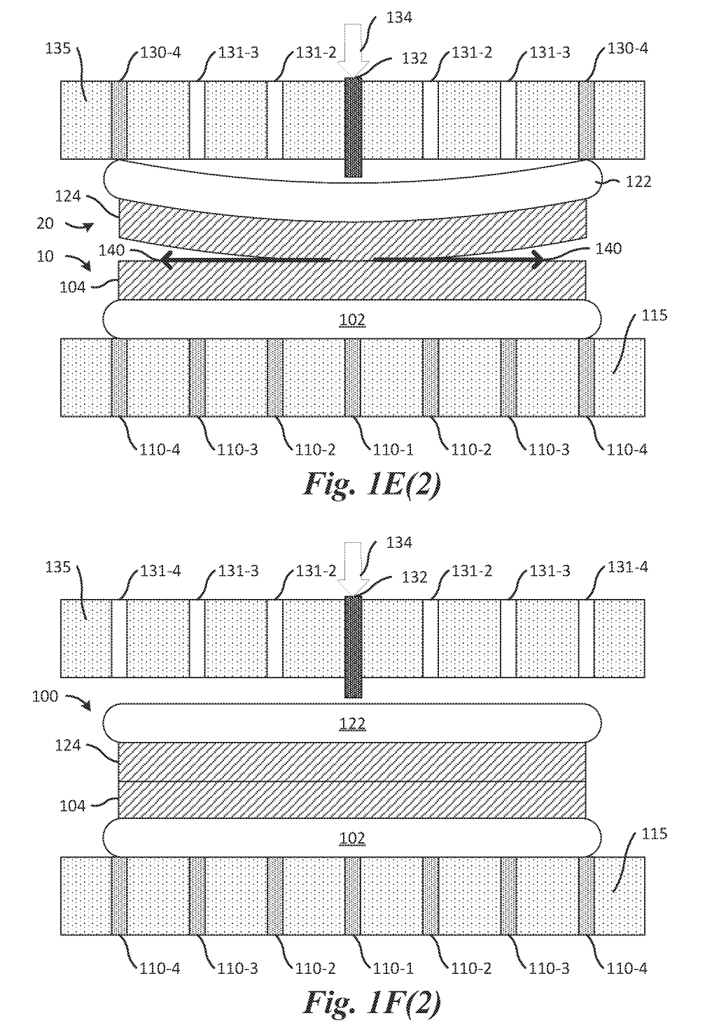

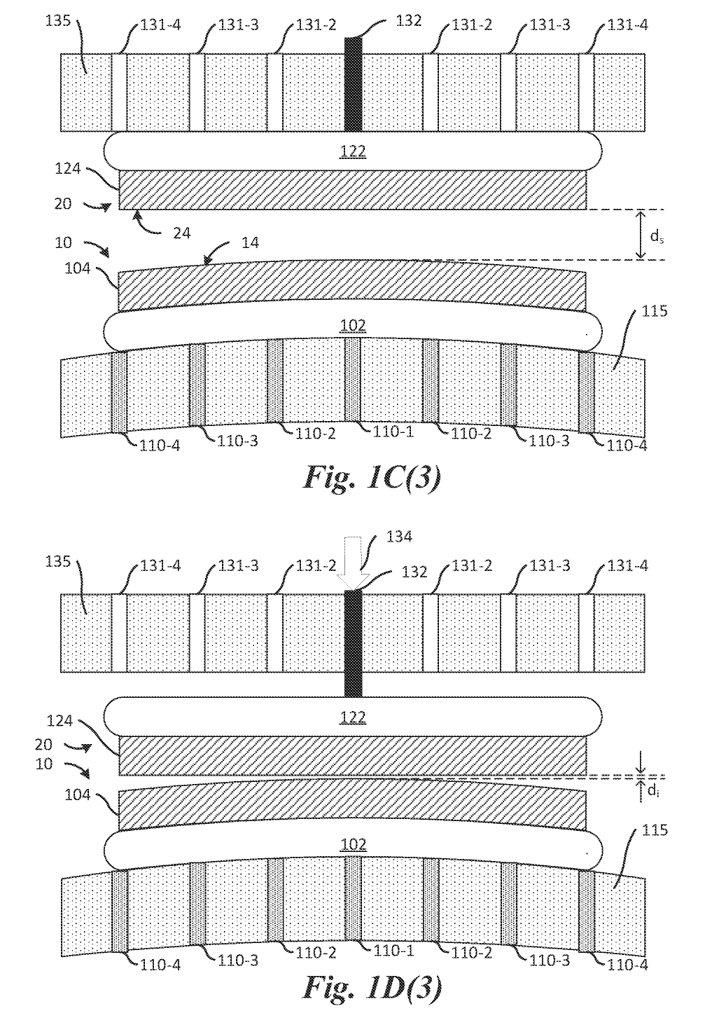

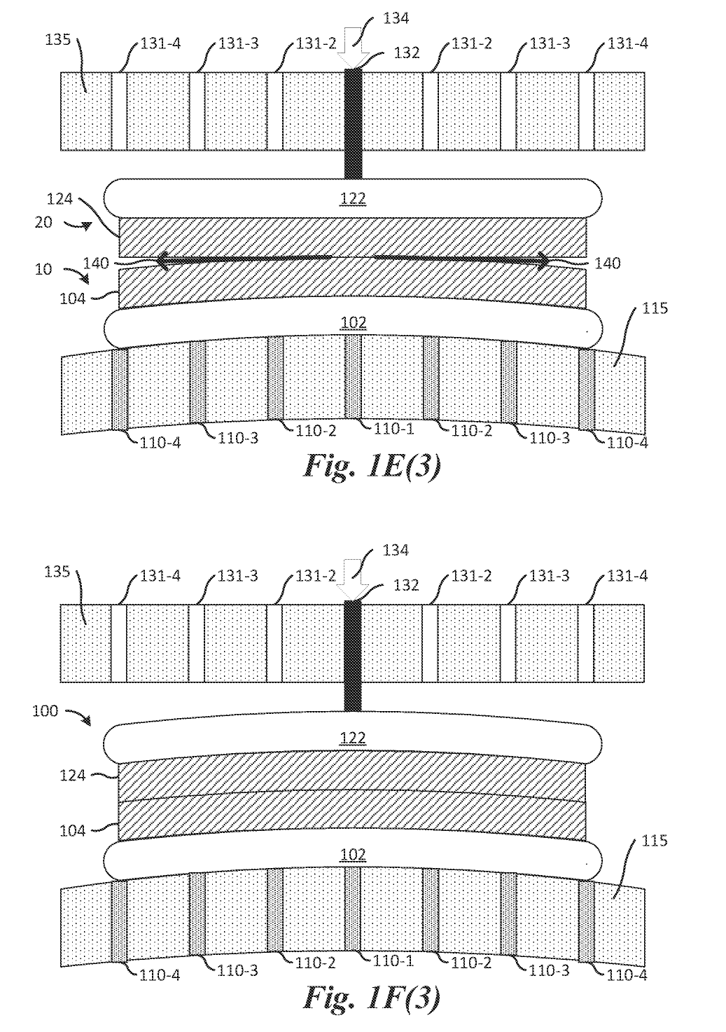

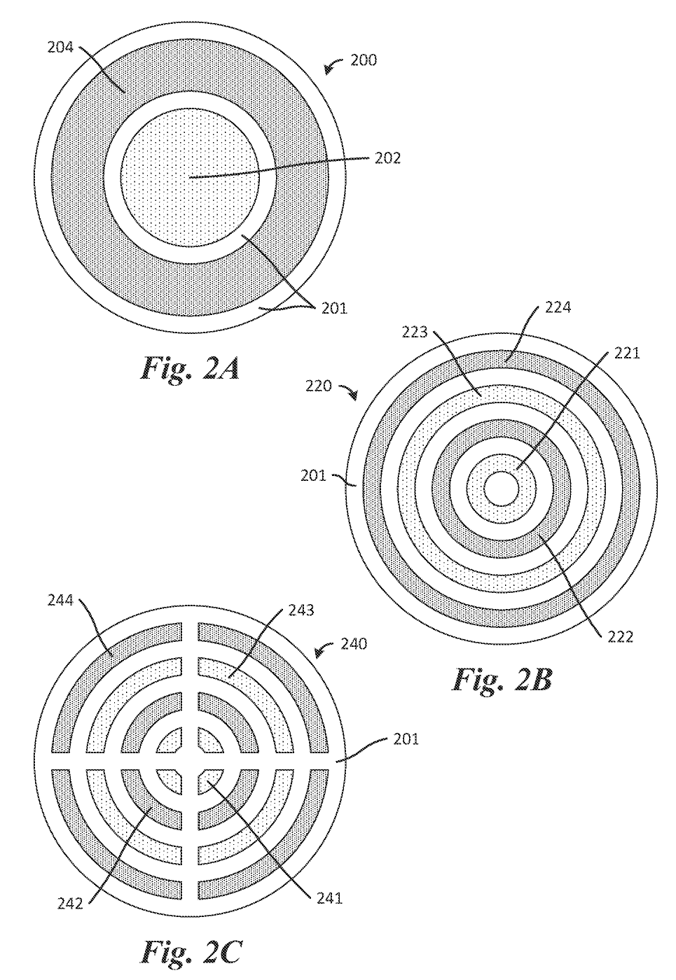

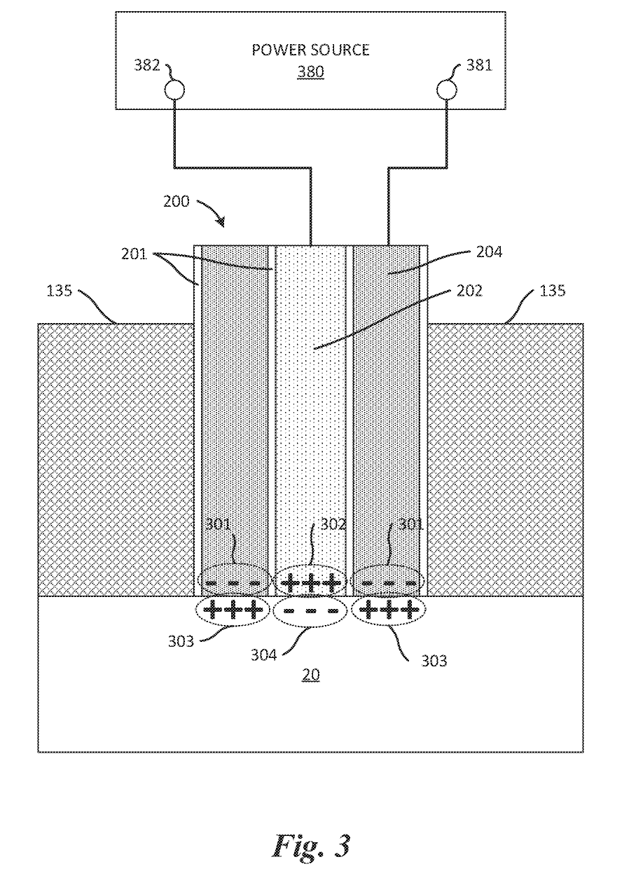

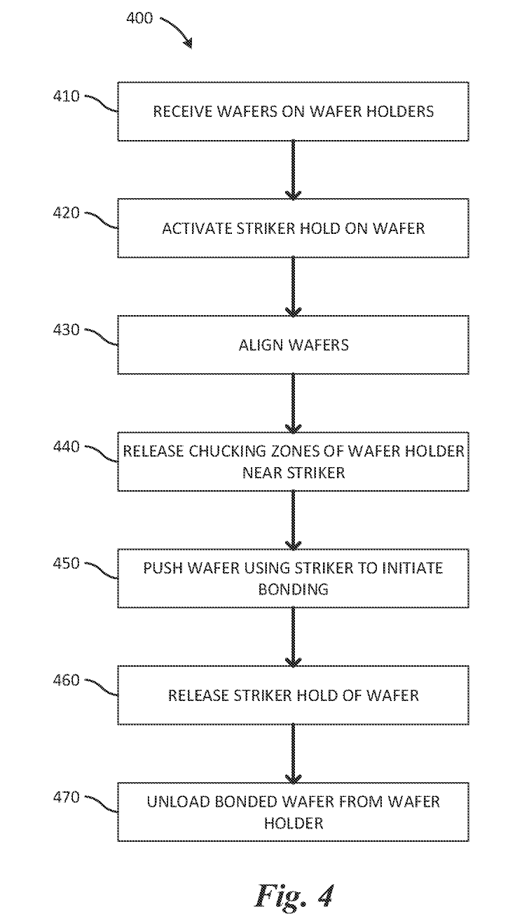

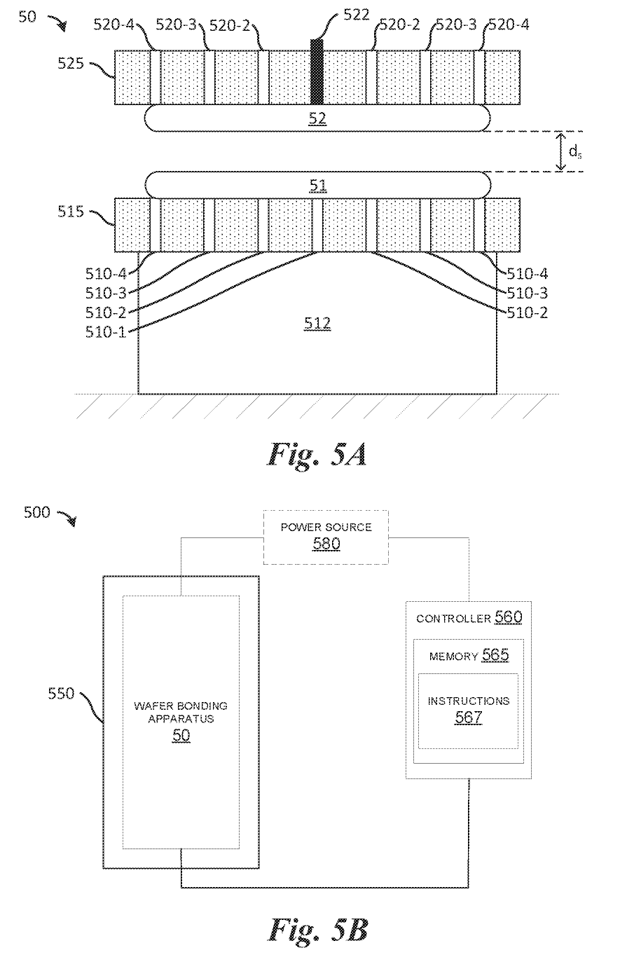

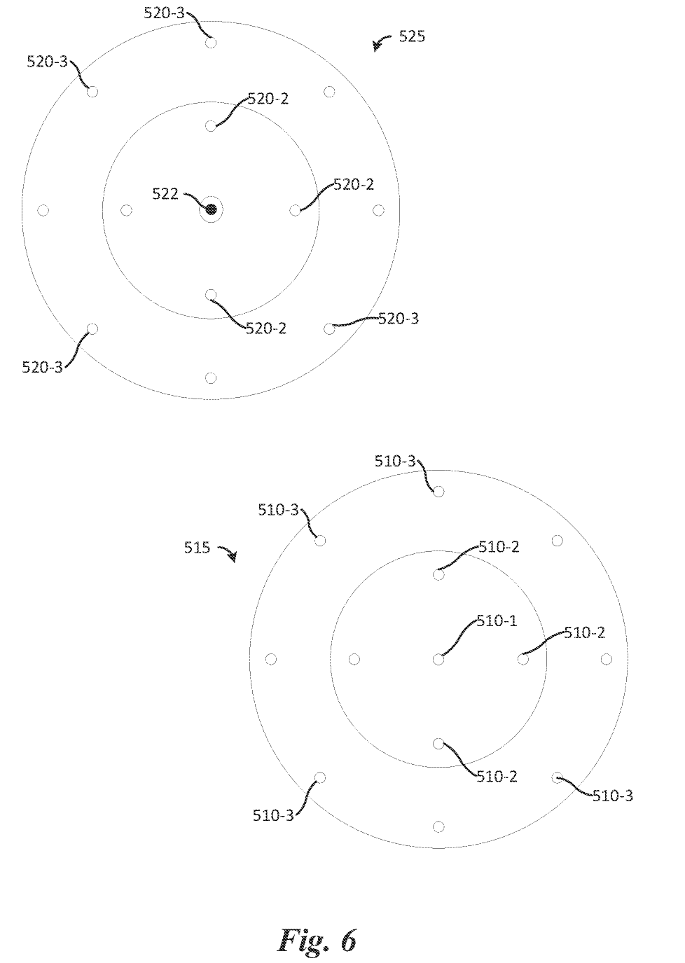

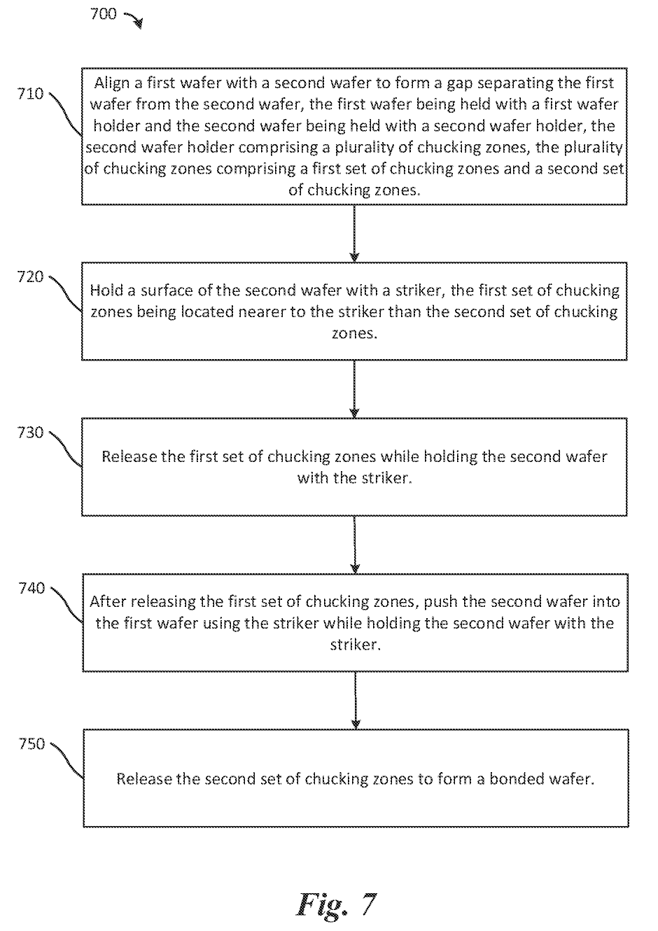

Embodiments provided below describe various methods, apparatuses and systems for bonding wafers, and in particular, to methods, apparatuses, and systems that use a striker to hold a wafer and push the wafer into another wafer to initiate bonding while maintaining control of a region of the wafer held by the striker. The following description describes the embodiments. FIGS. 1A-1H describe an example bonding method for bonding wafers using a striker to hold and push a wafer into another wafer to initiate bonding while maintaining control of a region of the wafer held by the striker. FIGS. 2A-2C describe various embodiments of the striker which may be used to perform the bonding method of FIGS. 1A-1H. FIG. 3 illustrates how an embodiment of the striker of FIG. 2A holds a wafer. A flowchart of the bonding method of FIGS. 1A-1H is described using FIG. 4. An example wafer bonding apparatus and an example wafer bonding system capable of implementing the wafer bonding method of this disclosure are described using FIGS. 5A-5B. Example embodiments of wafer holders which may be used to hold wafers during the bonding method of this disclosure are described using FIG. 6. And the flowchart of FIG. 7 illustrates an embodiment bonding method of the bonding method described using FIGS. 1A-1H.

FIGS. 1A-1H illustrate cross-sectional views of wafers during various steps of a wafer bonding method of this disclosure. In the wafer bonding method illustrated in FIGS. 1A-1H, a striker capable of holding a wafer may be used to lower the wafer to initiate bonding after releasing the wafer from a wafer holder.

Now referring to FIG. 1A, the wafer bonding method of this disclosure may start by receiving a first wafer 10 in a suitable processing chamber for forming a bonded wafer. The first wafer 10 may be received in a first wafer holder 115, and the first wafer holder 115 may be activated to hold the first wafer 10 during the bonding method. As illustrated in FIG. 1A, the first wafer 10 comprises a topside 14, a first substrate 102, and first layers 104.

In one or more embodiments, the first substrate 102 may be a silicon wafer, or a silicon-on-insulator (SOI) wafer. In certain embodiments, the first substrate 102 may comprise a silicon oxide (glass/quartz) wafer, silicon germanium wafer, silicon carbide wafer, gallium arsenide wafer, gallium nitride wafer and other compound semiconductors. In other embodiments, the first substrate 102 comprises heterogeneous layers such as silicon germanium on silicon, gallium nitride on silicon, silicon carbon on silicon, as well as layers of silicon on a silicon or SOI substrate. In various embodiments, the first substrate 102 may be a component of, or comprise, a semiconductor device (e.g., a transistor), and may have undergone various processing steps following, for example, a conventional process recipe. For example, the first wafer 10 may comprise the first substrate 102 in which various device regions are formed.

In various embodiments, the first layers 104 may comprise various metallization layers, dielectric layers, device layers of a device being fabricated, and a bonding layer for bonding the first wafer 10 with another wafer. Further, the first layers 104 may be formed using a conventional process using suitable deposition, patterning, and etching techniques to form the first layers 104. In various embodiments, the first layers 104 may comprise a dielectric material. In certain embodiments, the first layers 104 may comprise a silicon oxide layer. In alternate embodiments, the first layers 104 may comprise silicon nitride, silicon oxynitride, or an O/N/O/N layer stack (stacked layers of oxide and nitride). The first layers 104 may be deposited using an appropriate technique such as vapor deposition including chemical vapor deposition (CVD), physical vapor deposition (PVD), atomic layer deposition (ALD), as well as other plasma processes such as plasma enhanced CVD (PECVD) and other processes. In one embodiment, the first layers 104 have a thickness between 1 µm and 10 µm. In another embodiment, the first layers 104 may comprise a back end of line (BEOL) layer disposed over a front end of line (FEOL) layer.

In one or more embodiments, the first layers 104 may comprise a bonding layer formed from any suitable bonding material deposited through a deposition process. For example, in various embodiments, a bonding layer of the first layers 104 may comprise tetraethyl orthosilicate (TEOS), silicon oxide, silicon nitride, silicon oxynitride, polymers, organic adhesive layers, or glass. In other embodiments, the first layers 104 may comprise layers suitable for hybrid bonding embodiments. For example, the first layers 104 may comprise electrical contacts (such as copper contacts) and a bonding layer formed from any suitable bonding material (such as tetraethyl orthosilicate (TEOS), silicon oxide, silicon nitride, silicon oxynitride, polymers, organic adhesive layers, or glass), where the electrical contacts may be aligned to form electrical pathways through a bonding interface formed from bonding the first wafer 10 with another wafer.

In various embodiments, the first wafer holder 115 may be a part of a wafer bonding apparatus configured to bond the first wafer 10 with another wafer. The first wafer holder 115 comprises a first vacuum nozzle 110-1 disposed in a center of the first wafer holder 115, a plurality of second vacuum nozzles 110-2 disposed around the first vacuum nozzle 110-1, a plurality of third vacuum nozzles 110-3 disposed around the first vacuum nozzle 110-1 at a larger radial distance than the plurality of second vacuum nozzles 110-2, and a plurality of fourth vacuum nozzles 110-4 disposed around the first vacuum nozzle 110-1 at an even larger radial distance than the plurality of third vacuum nozzles 110-3. The first wafer holder 115 comprises concentric chucking zones, where each of the concentric chucking zones comprises a set of the various vacuum nozzles (110-1 – 110-4). Other embodiments may use more or less of the various vacuum nozzles (110-1 – 110-4) and may use different diameters.

The first wafer holder 115 may be substantially planar (or flat) such that the entire back surface of the first wafer 10 contacts the various vacuum nozzles (110-1 – 110-4). In other words, the first wafer holder 115 comprises a planar surface configured to hold the first wafer 10 during bonding. In one or more embodiments, the first wafer holder 115 comprises a vacuum chuck, and the various vacuum nozzles (110-1 – 110-4) comprise various vacuum nozzles configured to hold the first wafer 10 by using a vacuum. Further, the various vacuum nozzles (110-1 – 110-4) may be configured such that each is independently controllable, which may enable a chucking sequence (or loading sequence) where the various vacuum nozzles (110-1 – 110-4) may be sequentially activated as desired to bring the entirety of the first wafer 10 into contact with the first wafer holder 115.

The various vacuum nozzles (110-1 – 110-4) of the first wafer holder 115 may have been activated according to a chucking sequence to receive and hold the first wafer 10 after positioning and aligning the first wafer 10 as may be desired for the bonding method of this disclosure. After receiving and holding the first wafer 10 in the first wafer holder 115 in FIG. 1A, the bonding method may proceed to the step illustrated in FIG. 1B.

FIG. 1B illustrates a cross-sectional view of a second wafer 20 after receiving the second wafer 20 on a second wafer holder 135 to be bonded with the first wafer 10 on the first wafer holder 115. Further, FIG. 1B illustrates the second wafer 20 after activating the second wafer holder 135 through a chucking process to hold the second wafer 20 during the bonding method, after positioning and aligning the first wafer 10 and the second wafer 20 as may be desired for forming a suitably aligned bonded wafer, and after bringing the first wafer 10 and the second wafer 20 to a separation distance (dₛ) as specified for the bonding method of this disclosure using the first wafer holder 115 and the second wafer holder 135.

As illustrated in FIG. 1B, the separation distance (dₛ) is the distance between a topside 24 of the second wafer 20 and the topside 14 of the first wafer 10. In various embodiments, the separation distance (dₛ) may be predetermined for the bonding method, where the separation distance (dₛ) is suitable for initiating bonding between the first wafer 10 and the second wafer 20. In those embodiments, the separation distance (dₛ) may vary between 1µm and 200µm.

The second wafer 20 comprises second layers 124 disposed over a second substrate 122. Further, the second wafer 20 may be loaded on the second wafer holder 135 such that the second substrate 122 contacts the second wafer holder 135. In various embodiments, the second layers 124 may be as described for the first layers 104, and the second substrate 122 may be as described for the first substrate 102. In one or more embodiments, the second layers 124 may comprise electrical contacts (such as copper) and a bonding layer to be aligned and bonded with the first wafer 10 such that electrical pathways are formed through a bonding interface formed by bonding the first wafer 10 with the second wafer 20, where the electrical pathways may be formed between electrical contacts of the first layers 104 and electrical contacts of the second layers 124.

In the embodiment illustrated in FIG. 1B, the second wafer holder 135 is a vacuum chuck that is substantially flat. The second wafer holder 135 comprises various vacuum nozzles (130-2 – 130-4), which may be as described for the various vacuum nozzles (110-1 – 110-4) of the first wafer holder 115. Additionally, the second wafer holder 135 comprises a striker 132 disposed in a center of the second wafer holder 135, a plurality of second vacuum nozzles 130-2 disposed around the striker 132, a plurality of third vacuum nozzles 130-3 disposed around the striker 132 at a larger radial distance than the plurality of second vacuum nozzles 130-2, and a plurality of fourth vacuum nozzles 130-4 disposed around the striker 132 at an even larger radial distance than the plurality of third vacuum nozzles 130-3. In FIG. 1B, the various vacuum nozzles (130-2 – 130-4) and the striker 132 have been activated to hold the second wafer 20 on the second wafer holder 135.

In contrast to conventional embodiments, the striker 132 of this disclosure is configured to hold and push the second wafer 20 into the first wafer 10 rather than striking the second wafer 20 into the first wafer 10. This may be accomplished through a suitable chucking configuration of the striker 132. For example, in various embodiments, the striker 132 comprises electrodes oppositely biased to enable the striker 132 to hold the second wafer 20 using an electrostatic force. As another example, in other embodiments, the striker 132 comprises one or more vacuum nozzles to enable the striker 132 to hold the second wafer 20 using a pressure differential. During the chucking process of loading the second wafer 20 on the second wafer holder 135, the various vacuum nozzles (130-2 – 130-4) and the striker 132 may be activated in a suitable sequence to hold the second wafer 20 to the second wafer holder 135. Embodiments of the striker 132 are further described using FIGS. 2A-2C and 3, and embodiments of the first wafer holder 115 and the second wafer holder 135 are described further using FIG. 6.

FIG. 1C(1) illustrates a cross-sectional view of the second wafer 20 and the first wafer 10 after deactivating vacuum nozzles disposed proximal the striker 132. In the embodiment illustrated in FIG. 1C(1), the second vacuum nozzles 130-2 released the second wafer 20 to become released second vacuum nozzles 131-2, and the third vacuum nozzles 130-3 released the second wafer 20 to become released third vacuum nozzles 131-3.

FIG. 1D(1) illustrates the striker 132 pushing 134 the second wafer 20 towards the first wafer 10 while the striker 132 holds the second wafer 20, the pushing 134 bringing the second wafer 20 to an initiation distance (dᵢ) between the second wafer 20 and the first wafer 10. The bond front 140 may propagate from a center of the first wafer 10 and the second wafer 20 to outer edges of the first wafer 10 and the second wafer 20. During the bond front 140 propagation, the various remaining active vacuum nozzles (130-4) of the second wafer holder 135 may be systematically controlled to advantageously release the second wafer 20 to adjust a propagation speed of the bond front 140. For example, the various remaining active vacuum nozzles (130-4) may be controlled to increase or decrease the propagation rate of the bond front 140 as desired.

The striker 132 closes the separation distance (dₛ) between the first wafer 10 and the second wafer 20 by pushing 134 the second wafer 20 into the first wafer 10 to the initiation distance (dᵢ). Consequently, a symmetrical stretch may be formed in the second wafer 20 by the pushing 134. In various embodiments, the symmetrical stretch of the second wafer 20 may be a complimentary stretch, or a dilation of the second wafer 20. In some embodiments, the first wafer holder 115 may be curved (or bowed) such that a complimentary stretch is formed in the first wafer 10 as is formed by pushing 134 the second wafer 20 into the first wafer 10, where dilations and misalignment may be further prevented by similarly stretching both wafers. An example embodiment where the first wafer holder 115 is curved (or bowed) is described using FIGS. 1C(3)-1F(3) below. During the pushing 134, the striker 132 actively holds the second wafer 20.

FIG. 1E(1) illustrates a cross-sectional view of the striker 132 pushing 134 the second wafer 20 into the first wafer 10 to initiate a bond front 140 propagating across surfaces between the wafers and initiating bonding, the pushing 134 overcoming the initiation distance (dᵢ). The pushing 134 may be performed at any desired rate, such as either slowly or quickly. In various embodiments, as the bond front 140 propagates across surfaces between the first wafer 10 and the second wafer 20, remaining active vacuum nozzles (130-4) may be released in a dechucking sequence which may be determined to control a rate of propagation of the bond front 140. Further, the striker 132 holds the second wafer 20 during the step illustrated in FIG. 1E(1), where the striker 132 continues pushing 134 the second wafer 20 into the first wafer 10.

FIG. 1F(1) illustrates a cross-sectional view of the second wafer 20 and the first wafer 10 after releasing the remaining active vacuum nozzles (130-4) to become released fourth vacuum nozzles 131-4 and enable the bond front 140 to fully propagate between the wafers and form a bonded wafer 100. Again, the pushing 134 may be maintained until the bonding has been completed between the first wafer 10 and the second wafer 20. In other embodiments, all the various vacuum nozzles (130-2 – 130-4) may be released such that the second wafer 20 is only held by the striker 132, which may then push the second wafer 20 into the first wafer 10 to initiate the bond front and form the bonded wafer 100, where such an embodiment is described using FIGS. 1C(3)-1F(3) below.

FIG. 1G illustrates a cross-sectional view of the bonded wafer 100 after releasing the hold of the striker 132 and ending the pushing 134 such that a released striker 133 no longer holds the second wafer 20 of the bonded wafer 100. In an embodiment where the striker 132 holds the second wafer 20 through an electrostatic force, the bias power applied to electrodes of the striker 132 may be powered off, or the striker 132 may be grounded to deplete accumulated charge. In other embodiments where the striker 132 comprises a vacuum nozzle to hold the second wafer 20 through a pressure differential, the vacuum nozzle of the striker 132 may be turned off to release the second wafer 20.

FIG. 1H illustrates a cross-sectional view of the bonded wafer 100 after raising the released striker 133, and after releasing the first wafer 10 from the first wafer holder 115, the various vacuum nozzles (110-1 – 110-4) becoming released vacuum nozzles (111-1 – 111-4). In one or more embodiments, the first wafer 10 may be released from the first wafer holder 115 through a dechucking process, which may comprise the same steps as the chucking process to load the first wafer 10 on the first wafer holder 115, but in reverse. In various embodiments, the bonded wafer 100 may be further processed after releasing the bonded wafer 100 from the first wafer holder 115. For example, in one or more embodiments, the bonded wafer 100 may be annealed to improve bond strength and finish forming the bonded wafer 100.

The wafer bonding method described using FIGS. 1A-1H may prevent center distortions during wafer-to-wafer bonding by holding the second wafer 20 using the striker 132 during the bonding. In other embodiments, the wafer bonding method may use multiple strikers, each capable of holding regions of the surface of the second wafer 20 during bonding such that the second wafer 20 remains stationary during bonding. Consequently, the wafer bonding method of this disclosure may form the bonded wafer 100 with less center distortions than conventional methods by using a striker capable of holding the second wafer 20 during the bonding and pushing the second wafer 20 into the first wafer 10 to initiate bonding.

In another embodiment, the striker 132 may be used to generate a repulsive electrostatic force, which may be used to push the second wafer 20 into the first wafer 10 to initiate bonding, such as described using FIGS. 1C(2)-1F(2). The steps of FIGS. 1C(2)-1F(2) may be used in place of the steps described using FIGS. 1C(1)-1F(1) above.

FIG. 1C(2) illustrates the second wafer 20 loaded on the second wafer holder 135 with the various vacuum nozzles (130-2 – 130-4) active and the striker 132 actively generating a repulsive electrostatic force without contacting the second wafer 20. FIG. 1D(2) illustrates using the striker 132 to begin pushing 134 the second wafer 20 (without contacting the second wafer 20 with the striker 132) until the gap separating the first wafer 10 and the second wafer 20 is an initiation distance (dᵢ), and after releasing various vacuum nozzles disposed near the striker 132 to be the released vacuum nozzles (131-2 – 131-3). In one or more embodiments, a first set of vacuum nozzles of the second wafer holder 135 may comprise the second vacuum nozzles 130-2 and the third vacuum nozzles (130-3). Similarly, a second set of vacuum nozzles of the second wafer holder 135 may comprise remaining vacuum nozzles 130-4, where the first set of vacuum nozzles are nearer the striker 132 than the second set of vacuum nozzles.

In various embodiments, the repulsive electrostatic force may be generated using a power source to apply a bias voltage to the striker 132 and to the second wafer 20 of the same polarity such that same polarity charge accumulations between the striker 132 and the second wafer 20 each repel the other. Further details of how the repulsive electrostatic force may be generated are discussed using FIG. 3 below.

After, the wafer bonding method may proceed to the step illustrated in FIG. 1E(2). In FIG. 1E(2), the striker 132 continues pushing 134 the second wafer 20 into the first wafer 10 using the repulsive electrostatic force of the striker 132 to initiate the bond front 140 propagating between surfaces of the wafers. And in FIG. 1F(2), the striker 132 continues the pushing 134 of the second wafer 20 into the first wafer 10 while advantageously controlling the release sequence of the remaining vacuum nozzles (130-4) to control the propagation rate of the bond front 140 and form the bonded wafer 100. After the step illustrated in FIG. 1F(2), the wafer bonding method may proceed with the steps described using FIGS. 1G-1H above, where the striker 132 is deactivated and moved away from the surface of the second wafer 20.

And in yet another embodiment, the striker 132 may completely hold the second wafer 20 and lower the second wafer 20 into the first wafer 10 to initiate bonding after completely releasing all vacuum nozzles (130-2 – 130-4) of the second wafer holder 135, where the first wafer 10 is loaded on a curved (or bowed) first wafer holder 115 which may form a symmetric stretch in the first wafer 10, such as described using FIGS. 1C(3)-1F(3). The steps of FIGS. 1C(3)-1F(3) may be used in place of the steps described using FIGS. 1C(1)-1F(1) above.

FIG. 1C(3) illustrates a step of the wafer bonding method where the striker 132 is activated and is holding the second wafer 20, and the vacuum nozzles of the second wafer holder 135 are released vacuum nozzles (131-2 – 131-4) such that the second wafer 20 is only held by the striker 132. The striker 132 may hold the second wafer 20 through an electrostatic force, or through a pressure differential using vacuum nozzles in the striker 132. Further, in the embodiment illustrated in FIG. 1C(3), the first wafer 10 is loaded on a curved (or bowed) first wafer holder 115, which forms a symmetric stretch in the first wafer 10. In FIG. 1D(3), the striker 132 begins lowering the second wafer 20 to a gap separating the second wafer 20 and the first wafer 10 which may be an initiation distance (dᵢ), where the lowering comprises pushing 134 using the striker 132.

FIG. 1E(3) illustrates the pushing 134 by the striker 132 of the second wafer 20 into the first wafer 10 to overcome the initiation distance (dᵢ) and initiate a bond front 140 propagating between surfaces of the wafers to bond the second wafer 20 and the first wafer 10. And FIG. 1F(3) illustrates the pushing 134 by the striker 132 of the second wafer 20 into the first wafer 10 until the bond front 140 fully propagates across the bonding interface between the wafers, which forms the bonded wafer 100. After, the wafer bonding method may resume with the steps described using FIGS. 1G-1H above, where the striker 132 is deactivated and moved away from the surface of the second wafer 20.

FIGS. 2A-2C are schematic diagrams of striker embodiments which may be used in the wafer bonding method described using FIGS. 1A-1H above, where the striker embodiments are illustrated as cross-sectional slices.

FIG. 2A illustrates a schematic diagram of a striker 200 comprising a first chucking zone 202 and a second chucking zone 204 separated by isolation regions 201. The striker 200 may be used in the wafer bonding method of this disclosure to hold and push one wafer into another to form a bonded wafer. For example, the striker 200 may be used as the striker 132 in FIGS. 1A-1H.

In an embodiment, the striker 200 may be configured to hold a wafer using an electrostatic force, where the first chucking zone 202 comprises a first electrode which may be biased at a first polarity and the second chucking zone 204 comprises a second electrode which may be biased at a second polarity (opposite the first polarity). The first electrode and the second electrode may be made from conventional materials used in electrostatic chucks, such as metals and alloys, conductive ceramics, or polymers with conductive fillers. Further, the first electrode and the second electrode may comprise aluminum, copper, tungsten, titanium, doped silicon carbide, doped aluminum nitride, doped aluminum oxide or specialized polymers. In an embodiment, an insulating layer separates the striker 200 from a wafer such that the striker 200 is configured to hold the wafer during the bonding through the insulating layer preventing the striker 200 from directly contacting the wafer. In those embodiments, the insulating layer contacts the wafer, and the insulating layer may comprise any suitable insulating material such as ceramics, glass ceramics, polymeric materials, aluminum oxide, aluminum nitride, silicon nitride, silicon carbide, specialized glass ceramic materials, or high-performance polymers like polyimide. Additionally, the first electrode and the second electrode of the striker 200 may be biased using conventional power sources, such as using a DC power supply. The biasing power applied to the first electrode and the second electrode may be opposite polarity DC potentials comprising amplitudes varying between 0V and 5000V.

In those embodiments where the first chucking zone 202 and the second chucking zone 204 comprise electrodes, the isolation region 201 may be formed to electrically isolate the electrodes of the striker 200. The isolation region 201 may comprise insulators such as ceramics, glass ceramics, or polymeric materials. Further, the isolation region 201 may comprise aluminum oxide, aluminum nitride, silicon nitride, silicon carbide, specialized glass ceramic materials, or high-performance polymers like polyimide.

In other embodiments, the striker 200 may comprise vacuum nozzles, where the first chucking zone 202 and the second chucking zone 204 each comprise one or more vacuum nozzles capable of holding the second wafer 20 through pressure differentials. The vacuum nozzles of the first chucking zone 202 and the second chucking zone 204 may comprise conventional vacuum nozzle materials and may be similarly formed through conventional methods.

FIG. 2B illustrates a schematic diagram of a striker 220 comprising alternating chucking zones separated by isolation regions 201. The alternating chucking zones comprise a first chucking zone 221, a second chucking zone 222, a third chucking zone 223, and a fourth chucking zone 224.

As illustrated in FIG. 2B, working from the inside to the outside, an isolation region 201 may be disposed in the center of the striker 220, which may be surrounded by the first chucking zone 221. Another isolation region 201 surrounds the first chucking zone 221, which are both surrounded by a second chucking zone 222. Another isolation region 201 surrounds the second chucking zone 222, which are both surrounded by the third chucking zone 223, followed by another isolation region 201, and then the fourth chucking zone 224 and a final isolation region 201. Other embodiments may comprise different amounts of chucking zones as desired for the striker 220 to hold a wafer during the bonding method of this disclosure.

In an electrostatic embodiment of the striker 220, the various chucking zones each comprise electrodes which may be alternating in bias potential working from the inside to the outside. In those embodiments, the electrodes may be as similarly described for the striker 200 in FIG. 2A. And in a vacuum embodiment of the striker 220, the various chucking zones each comprise one or more vacuum nozzles which may be individually controlled to hold the second wafer 20.

FIG. 2C illustrates a schematic diagram of a striker 240 comprising alternating chucking zones separated by isolation regions 201, where chucking zones of the alternating chucking zones are segmented. In the embodiments illustrated in FIG. 2C, the alternating chucking zones are segmented into four segments, each capable of being similarly or oppositely biased from another segment of the same chucking zone. In one or more embodiments, the alternating chucking zones may be segmented into as many segments as desired for forming the striker 240 capable of holding a wafer during the wafer bonding method of this disclosure.

The striker 240 comprises a first chucking zone 241, a second chucking zone 242, a third chucking zone 243, and a fourth chucking zone 244, where each of the various alternating chucking zones may be separated by the isolation regions 201. Further, each of the various alternating chucking zones (241-244) may be as similarly described for the various alternating chucking zones (221-224) of the striker 220 in FIG. 2B. Though the various alternating chucking zones (241-244) are segmented in a cross-like shape in FIG. 2C, other shapes may be formed by segmenting each chucking zone less or more in various embodiments. And as was described for the striker 220 in FIG. 2B, the striker 240 of FIG. 2C may be an electrostatic striker, where the various alternating chucking zones (241-244) comprise electrodes of alternating polarity which may be used to hold a wafer using an electrostatic force. In other embodiments, the various chucking zones may comprise one or more vacuum nozzles capable of being individually controlled to hold the second wafer 20 during the wafer bonding method of this disclosure.

FIG. 3 illustrates an electrostatic embodiment of the striker 200 of FIG. 2A holding the second wafer 20 disposed on the second wafer holder 135 during the wafer bonding method of FIGS. 1A-1H. In the embodiment illustrated in FIG. 3, the striker 200 comprises the first chucking zone 202 concentrically surrounded by the second chucking zone 204, where the first chucking zone 202 comprises a first electrode and the second chucking zone 204 comprises a second electrode. Further, the striker 200 is coupled to a power source 380 configured to bias the first chucking zone 202 and the second chucking zone 204 to generate an electrostatic force to hold the second wafer 20.

The striker 200 holds the second wafer 20 using an electrostatic force, which may be generated by applying a first voltage (or biasing voltage) of a first polarity to the first chucking zone 202 and by applying a second voltage of a second polarity to the second chucking zone 204. In the embodiment illustrated in FIG. 3, the first polarity may be a positive voltage that varies between 500V and 2000V which accumulates positive charge 302 in the first chucking zone 202 proximal the second wafer 20. In that same embodiment, the second polarity may be a negative voltage that varies between -500V and -2000V which accumulates negative charge 301 in the second chucking zone 204 proximal the second wafer 20. Consequently, the accumulation of positive charge 302 and negative charge 301, and the application of the biasing voltages by the power source 380 may accumulate reactionary positive charges 303 and reactionary negative charges 304 in the second wafer 20. In other embodiments, AC voltages may be used to bias the electrodes of the striker 200.

The accumulation of the various charges results in an electrostatic force, or an attraction, between the accumulation of the various charges, where the positive charge 302 in the first chucking zone 202 attracts the reactionary negative charges 304 in the second wafer 20, and the negative charge 301 in the second chucking zone 204 attracts the reactionary positive charges 303 in the second wafer 20. And through the attractions of the various charges disposed between the chucking zones of the striker 200 and the second wafer 20, the striker 200 may hold a surface of the second wafer 20 during the wafer bonding method of this disclosure.

In various embodiments, the power source 380 may be any device capable of generating electrical potentials which may be used to bias the first chucking zone 202 and the second chucking zone 204 of the striker 200. For example, the power source 380 may be a DC power supply or an AC power supply, or other conventional devices capable of generating biasing potentials. In the embodiment illustrated in FIG. 3, the power source 380 comprises a first connector 382 and a second connector 381, where the first connector 382 is electrically coupled with the first chucking zone 202, and where the second connector 381 is electrically coupled with the second chucking zone 204. In one or more embodiments, the first connector 382 and the second connector 381 may be electrodes of the power source 380.

Still referring to FIG. 3, in an embodiment where the striker 200 may be used in the wafer bonding method described using FIGS. 1C(2)-1F(2), the power source 380 may be used to apply a biasing voltage to the first chucking zone 202 and the second chucking zone 204 that is the same polarity as a bias applied to the second wafer 20 to generate a repulsive electrostatic force between the striker 200 and the second wafer 20.

FIG. 4 is a flowchart illustrating a method 400, which is an example wafer bonding method that uses a striker to hold and push a wafer into another wafer. For example, the method 400 may be the wafer bonding method described using FIGS. 1A-1H in an embodiment. In various embodiments, the method 400 may begin with step 410.

In step 410, the method 400 receives wafers on wafer holders. In various embodiments, the wafers may be the first wafer 10 and the second wafer 20, the wafer holders may be the first wafer holder 115 and the second wafer holder 135, and step 410 may be the steps described using FIGS. 1A-1B.

The wafers may be received on the wafer holders ready to be bonded, where one of the wafer holders comprises a striker capable of holding and pushing one wafer into the other, where the striker may be an electrostatic striker or a striker comprising a vacuum nozzle. In one or more embodiments, the striker may be as described for the various strikers (200, 220, and 240) of FIGS. 2A-2C. The wafer holders may be activated to hold the wafers using chucking mechanisms. In some embodiments, the wafers may be held on the wafer holders using an electrostatic chucking mechanism, where the wafer holders comprise various alternating electrodes disposed in concentric rings, or chucking zones. In other embodiments, the wafers may be held using concentric chucking zones comprising vacuum nozzles, where the wafer holders are vacuum chucks.

In step 420, the method 400 activates the striker to hold the wafer loaded on the wafer holder comprising the striker using the associated holding mechanism of the striker. For example, in an embodiment where the striker comprises vacuum nozzles configured to hold a surface of the wafer, a vacuum pump may be used to form a pressure differential to hold the wafer using the striker. In other embodiments where the striker comprises electrodes which may be oppositely biased, the electrodes of the striker may be oppositely biased to hold the surface of the wafer using an electrostatic force, such as described using FIG. 3 above.

After loading the wafers on the wafer holders and activating the holding mechanism of the striker, the method 400 aligns the wafers using the wafer holders in step 430. The wafers may be aligned such that connections between the wafers are suitably formed after bonding as desired. In step 440, the method 400 releases chucking zones of the wafer holder comprising the striker near the striker. Though the chucking zones near the striker are released, the striker continues to hold the wafer. In various embodiments, step 440 may be the step illustrated and described using FIG. 1C above.

Once chucking zones near the striker are released, the method 400 may proceed to step 450. In step 450, the method 400 pushes the wafer using the striker to initiate bonding with the other wafer. The pushing in step 450 pushes the wafer being held by the striker into contact with the other wafer to initiate bonding, such as by initiating a bond front propagating between the two wafers, where the bond front propagates across surfaces brought into contact by the pushing and forms a bonded wafer. In various embodiments, step 450 may be the step illustrated in FIGS. 1D-1F, where the pushing 134 by the striker 132 initiates the bond front 140 propagating between the first wafer 10 and the second wafer 20 to form the bonded wafer 100.

After pushing the wafer using the striker into the other wafer to initiate bonding and form a bonded wafer in step 450, the method 400 may proceed to step 460. In step 460, the method 400 releases the striker hold of the wafer being held by the striker. In one or more embodiments, the striker may then be raised along with the wafer holder comprising the striker. In various embodiments, step 460 may be as described for the step illustrated in FIGS. 1G-1H. And in further embodiments, after releasing the striker in step 460, the method 400 may proceed to step 470. In step 470, the method 400 may unload the bonded wafer from the wafer holder. In one or more embodiments, the unloading of the bonded wafer in step 470 may use a conventional dechucking process or release sequence.

In various embodiments, after unloading the bonded wafer from the wafer holder in step 470, the method 400 may perform an annealing step to finish forming the bonded wafer. In one or more embodiments, the annealing may be performed in a separate processing chamber from the bonding chamber used to perform steps 410-470. Conventional annealing methods may be used to anneal the bonded wafer. A wafer bonding system capable of performing the method 400 is described used FIGS. 5A-5B below.

FIGS. 5A-5B are schematic diagrams of a wafer bonding apparatus 50 and a wafer bonding system 500 capable of implementing the wafer bonding method described using FIGS. 1A-1H, or the wafer bonding method 400 of FIG. 4.

FIG. 5A illustrates an embodiment of the wafer bonding apparatus 50 which may be used for the wafer bonding method of this disclosure. The wafer bonding apparatus 50 comprises a first wafer holder 515 disposed on a base 512, and a second wafer holder 525. In various embodiments, wafer bonding apparatus 50 may be operated in a bonding chamber for controlling an environment during use, such as a vacuum chamber or a gas pressurized chamber. A first wafer 51 is loaded on the first wafer holder 515, the first wafer 51 being held by concentric chucking zones comprising various vacuum nozzles (510-1 – 510-4) of the first wafer holder 515. A second wafer 52 is loaded on the second wafer holder 525 using concentric chucking zones comprising various vacuum nozzles (520-2 – 520-4) of the second wafer holder 525 and brought into alignment within a gap separating the wafers which may be a separation distance (dₛ) of the first wafer 51. The second wafer holder 525 comprises a striker 522 which may be used to hold the second wafer 52 and push the second wafer 52 into the first wafer 51 to initiate bonding while controlling regions of the second wafer 52 held by the striker 522.

The base 512 assembly of the wafer bonding apparatus 50 comprises the first wafer holder 515 having a substantially planar upper surface configured to support the first wafer 51. The first wafer holder 515 may be formed from a material having high dimensional stability and minimal thermal expansion characteristics. The upper surface of the first wafer holder 515 comprises concentric chucking zones, such as the vacuum nozzles (510-1 – 510-4) or vacuum channels arranged in a predetermined pattern to securely hold the first wafer 51 during bonding operations. In various embodiments, the base 512 may comprise a temperature control system configured to maintain a wafer temperature during bonding operations. In further embodiments, the second wafer holder 525 may comprise the same materials as the first wafer holder 515, and may comprise a substantially planar mounting surface configured to hold the second wafer 52 during bonding operations.

In various embodiments, the striker 522 may be as described for the striker 132 in FIGS. 1B-1H, or as described for the strikers (200, 220, and 240) of FIGS. 2A-2C. In one or more embodiments, the first wafer 51 and the second wafer 52 may be as described for the first wafer 10 and the second wafer 20 of FIGS. 1A-1H. The first wafer holder 515 may be a vacuum chuck, and may be as described for the first wafer holder 115 of FIG. 1A-1H. The second wafer holder 525 may be a vacuum chuck, and may be as described for the second wafer holder 135 of FIGS. 1B-1H. Other embodiments of the first wafer holder 515 and the second wafer holder 525 may be described using FIG. 6 below. For example, in alternative embodiments, the first wafer holder 515 may be an electrostatic chuck (ESC) comprising concentric chucking zones which are electrodes, and the second wafer holder 525 may be an electrostatic chuck (ESC) comprising concentric chucking zones which are electrodes. And in further embodiments, one of the wafer holders may be a vacuum chuck while the other is an electrostatic chuck.

FIG. 5B illustrates the wafer bonding system 500 capable of implementing the wafer bonding method described using FIGS. 1A-1H. The wafer bonding system 500 comprises the wafer bonding apparatus 50 of FIG. 5A disposed in a bonding chamber 550, a power source 580, and a controller 560. The bonding chamber 550 may be an independent chamber, a chamber in a cluster tool, or part of a track system. As illustrated in FIG. 5B, the controller 560 comprises a memory 565 storing instructions 567 to be executed by the controller 560 to operate the wafer bonding apparatus 50. In one or more embodiments, the bonding chamber 550 may be used for controlling an environment during bonding, and the bonding chamber 550 may be a vacuum chamber or a gas pressurized chamber.

The controller 560 may be any device capable of implementing the instructions 567 stored in the memory 565 for controlling and operating the wafer bonding system 500 to implement the wafer bonding method of this disclosure. In the embodiment illustrated in FIG. 5B, the controller 560 is electrically coupled with the wafer bonding apparatus 50 and the bonding chamber 550. The controller 560 may be electrically coupled with the first wafer holder 515, the second wafer holder 525, and the striker 522 to control the positioning, loading, aligning, striking, releasing, and bonding of the first wafer 51 and the second wafer 52. For example, the controller 560 may control the second wafer holder 525 such that the second wafer 52 is brought to the separation distance (dₛ) between the first wafer 51 and the second wafer 52. As another example, the controller 560 may control the striker 522 such that the striker 522 holds the second wafer 52 through a vacuum nozzle or through an electrostatic force, and pushes the second wafer 52 into contact with the first wafer 51 while holding the second wafer 52 to bond the wafers and form a bonded wafer.

The memory 565 may be any device suitable for storing the instructions 567 to be executed by the controller 560, such as instructions for performing the wafer bonding method of FIGS. 1A-1H or the wafer bonding method 400 of FIG. 4. In various embodiments, the memory 565 may comprise RAM, ROM, PROM, EPROM, EEPROM, hard disk, or any other information processing device with which the controller 560 communicates, such as a server or computer. In further embodiments, the wafer bonding system 500 may comprise a detector configured to measure bond front propagation rates throughout the bonding process, such as a light detector. The light detector may be a camera, or other suitable imaging device capable of measuring the bond front propagation rate during the wafer bonding method of this disclosure.

In various embodiments where the striker 522 of the wafer bonding apparatus 50 uses an electrostatic force to hold the second wafer 52 during bonding, the wafer bonding system 500 further comprises a power source 580. The power source 580 may be any suitable device for biasing electrodes of the striker 522 such that the striker 522 can hold the second wafer 52, such as a DC power supply or multiple DC power supplies, or an alternating power source capable of supplying AC biasing potentials. In some embodiments, the wafer bonding system 500 may comprise as many power sources as there are electrodes disposed within the striker 522. The controller 560 may be electrically coupled with the power source 580 to control the holding of the second wafer 52 by the striker 522 during the wafer bonding method of this disclosure.

FIG. 6 illustrates a top view schematic diagram of the second wafer holder 525 and the first wafer holder 515 which may be used in the wafer bonding system 500 of FIGS. 5A-5B. In various embodiments, the first wafer holder 515 may be designed to optimize the ability to hold a wafer substantially flat. In other embodiments, the first wafer holder 515 may be designed to form a symmetric stretch in a wafer that mirrors a stretch formed in the other wafer by the striker 522 during the bonding method of this disclosure, where the first wafer holder 515 is curved to form the symmetric stretch. The second wafer holder 525 and the first wafer holder 515 are an example embodiment, and other embodiments may comprise different elements or parts suitable for performing the wafer bonding method of this disclosure. In the embodiment illustrated in FIG. 6, the second wafer holder 525 and the first wafer holder 515 are vacuum chucks comprising vacuum nozzles for holding wafers during bonding. Additionally, in FIG. 6, surfaces configured to hold wafers during bonding of the first wafer holder 515 and the second wafer holder 525 are substantially flat or planar to minimize surface variations and dilations in a resulting bonded wafer. Other embodiments may use curved wafer holders, which may be capable of implementing the bonding method of this disclosure.

In one or more embodiments, the second wafer holder 525 comprises the striker 522 disposed in a center of the second wafer holder 525, a plurality of second vacuum nozzles 520-2 disposed around the striker 522, and a plurality of third vacuum nozzles 520-3 disposed around the striker 522 at a larger radial distance than the plurality of second vacuum nozzles 520-2. The striker 522 may be of any suitable material, and shape for holding and pushing a wafer into the wafer held by the first wafer holder 515 to initiate bonding between wafers. Other embodiments may use more than one striker, or the striker 522 may be disposed over an edge of the wafer rather than the center. The striker 522 may use a vacuum nozzle to hold a wafer, or the striker 522 may use electrodes to generate an electrostatic force to hold a wafer during bonding. For example, the striker 522 may be as described for the strikers (200, 220, and 240) of FIGS. 2A-2C. Various other arrangements and numbers of vacuum nozzles can be used in different embodiments in the second wafer holder 525. For example, a number or a size of vacuum nozzles can vary in different embodiments. In some embodiments, different diameters of vacuum nozzles can be used together.

As noted, the operation of the various vacuum nozzles (520-2 – 520-3) of the second wafer holder 525 can be used for controlling the retention of a wafer during the wafer bonding method of this disclosure (such as the wafer bonding method described using FIGS. 1A-1H, or the wafer bonding method 400 described using FIG. 4). For example, a release sequence involving individual vacuum nozzles (520-2 – 520-3) may be used to release a top wafer as the direct bond front propagates outwards. In an embodiment, when measured bond front propagation data collected during the wafer bonding method indicate a deviance from a desired tolerance, such as an excessive degree of eccentricity of propagation of the bond front, corrective action with respect to the various vacuum nozzles (520-2 – 520-3) or with respect to the striker 522 holding the wafer can be taken to reduce the eccentricity. For example, the various vacuum nozzles (520-2 – 520-3) can be controlled with a desired vacuum pressure, such as to release the top wafer in situ during bond front propagation at such times and radial locations where the bond front has propagated too slowly, such as to accelerate the bond front. In other cases, the desired vacuum pressure may be maintained longer at such times and radial locations where the bond front has propagated too quickly, such as to retard the bond front. Additionally, the second plurality of vacuum nozzles 520-2 may be released prior to pushing the wafer using the striker 522 holding the wafer, and the third plurality of vacuum nozzles 520-3 may then be subsequently controlled in a release sequence to adjust the bond front propagation rate while holding and pushing the wafer using the striker 522.

Still referring to FIG. 6, in similar embodiments, the first wafer holder 515 comprises a first vacuum nozzle 510-1 disposed in a center of the first wafer holder 515, a plurality of second vacuum nozzles 510-2 disposed around the first vacuum nozzle 510-1, and a plurality of third vacuum nozzles 510-3 disposed around the first vacuum nozzle 510-1 at a larger radial distance than the plurality of second vacuum nozzles 510-2. Various other arrangements and numbers of vacuum nozzles can be used in different embodiments. For example, a number or a size of vacuum nozzles can vary in different embodiments. In some embodiments, different diameters of vacuum nozzles can be used together.

The first wafer holder 515 may be substantially flat or planar, and concentric chucking zones (the various vacuum nozzles (510-1 – 510-3)) may be distributed to enable the chucking on the first wafer holder 515. For example, a distance between adjacent chucking zones (vacuum nozzles) may decrease moving from the center to the outer edge of the first wafer holder 515 such that there is a higher density of chucking sites (or vacuum channels or electrodes) at the edges of the first wafer holder 515 than the center. In other embodiments, the first wafer holder 515 may be curved such that concentric chucking zones (the various vacuum nozzles (510-1 – 510-3)) may form a symmetric stretch in the wafer held on the first wafer holder 515.

In other embodiments, the first wafer holder 515 and the second wafer holder 525 may be electrostatic chucks (ESCs) comprising electrodes in the concentric chucking zones instead of the various vacuum nozzles (510-1 – 510-3, and 520-2 – 520-3).

FIG. 7 is a flowchart illustrating an example method of bonding wafers using a striker configured to hold and push one wafer into the other in accordance with embodiments of this disclosure. The method of FIG. 7 may be combined with other methods and performed using suitable systems and apparatuses as described herein, such as the wafer bonding system 500 and the wafer bonding apparatus 50 of FIGS. 5A-5B. Although shown in a logical order, the arrangement and numbering of the steps of FIG. 7 are not intended to be limiting.

Referring to FIG. 7, step 710 of a method 700 of bonding wafers aligns a first wafer with a second wafer to form a gap separating the first wafer from the second wafer, the first wafer being held with a first wafer holder and the second wafer being held with a second wafer holder, the second wafer holder comprising a plurality of chucking zones, the plurality of chucking zones comprising a first set of chucking zones and a second set of chucking zones. In various embodiments, the first wafer may be the first wafer 10, the second wafer may be the second wafer 20, the first wafer holder may be the first wafer holder 115, the second wafer holder may be the second wafer holder 135, the plurality of chucking zones may be the various vacuum nozzles (130-2 – 130-4), the first set of chucking zones may be the vacuum nozzles (130-2 – 130-3), and the second set of chucking zones may be the vacuum nozzles 130-4 of FIGS. 1A-1H. Similarly, in some embodiments, the first wafer may be the first wafer 51, the second wafer may be the second wafer 52, the first wafer holder may be the first wafer holder 515, the second wafer holder may be the second wafer holder 525, and the plurality of chucking zones may be the various vacuum nozzles (520-2 – 520-4) of FIGS. 5A-5B and FIG. 6. In various embodiments, step 710 may be the steps described using FIGS. 1A-1B, or steps 410-430 of the method 400 in FIG. 4.

After, the method 700 holds a surface of the second wafer with a striker in step 720, the first set of chucking zones being located nearer to the striker than the second set of chucking zones. In one or more embodiments, the striker may be as described for the strikers (200, 220, and 240) of FIGS. 2A-2C, or the strikers 132 and 522 of FIGS. 1A-1H or 5A-5B. The striker may hold a surface of the second wafer as described above using FIGS. 2A-2C, where the striker may use electrostatic forces generated by biasing electrodes, or vacuum nozzles to hold the surface of the second wafer. In an embodiment, step 720 may be the step described using FIGS. 1C(1), 1C(2), and 1C(3) or step 420 of the method 400 in FIG. 4. In step 730, the method 700 releases the first set of chucking zones while holding the second wafer with the striker. In various embodiments, step 730 may be illustrated by FIGS. 1C(1), 1C(2), and 1C(3), where various vacuum nozzles (130-2 – 130-3) were released to be released vacuum nozzles (131-2 – 131-3) and a region of the second wafer 20 proximal the striker 132 is held by the striker 132. In some embodiments, step 730 may be step 440 of the method 400 in FIG. 4.

In step 740, the method 700 pushes the second wafer into the first wafer using the striker while holding the second wafer with the striker after releasing the first set of chucking zones. In various embodiments, step 740 may be the steps illustrated and described using FIGS. 1D(1-3)-1E(1-3), or step 740 may be step 450 of the method 400 in FIG. 4. And in step 750, the method 700 releases the second set of chucking zones to form a bonded wafer.

Still referring to FIG. 7, the bonded wafer may be the bonded wafer 100 of FIGS. 1F(1-3)-1H, and step 750 may be the steps illustrated in FIGS. 1F(1-3)-1H in an embodiment. In other embodiments, step 750 may be steps 450-460 of the method 400 in FIG. 4. After forming the bonded wafer in step 750, additional steps may be performed to finish forming the bonded wafer, such as by releasing the striker like described using FIGS. 1G-1H and step 460 of the method 400 in FIG. 4 and then performing an annealing process like described after unloading the bonded wafer in step 470 of the method 400 in FIG. 4.

Example embodiments of the invention are described below. Other embodiments can also be understood from the entirety of the specification as well as the claims filed herein.

Example 1. A method for bonding wafers includes aligning a first wafer with a second wafer to form a gap separating the first wafer from the second wafer, the first wafer being held with a first wafer holder and the second wafer being held with a second wafer holder, the second wafer holder including a plurality of chucking zones, the plurality of chucking zones including a first set of chucking zones and a second set of chucking zones. The method further includes holding a surface of the second wafer with a striker, the first set of chucking zones being located nearer to the striker than the second set of chucking zones, and releasing the first set of chucking zones while holding the second wafer with the striker. And the method further includes, after releasing the first set of chucking zones, pushing the second wafer into the first wafer using the striker while holding the second wafer with the striker, and releasing the second set of chucking zones to form a bonded wafer.

Example 2. The method of example 1, where the releasing the second set of chucking zones includes releasing the second set of chucking zones after pushing the second wafer.

Example 3. The method of one of examples 1 or 2, where the releasing the second set of chucking zones includes releasing the second set of chucking zones before pushing the second wafer.

Example 4. The method of one of examples 1 to 3, where the striker includes a first electrode and a second electrode, the first electrode and the second electrode configured to hold the surface of the second wafer using an electrostatic force generated by applying a first voltage to the first electrode and a second voltage to the second electrode, the first voltage including a first polarity, the second voltage including a second polarity, the first polarity being opposite the second polarity.

Example 5. The method of one of examples 1 to 4, where the striker includes a vacuum nozzle, the vacuum nozzle configured to hold the surface of the second wafer using a pressure differential between the surface of the second wafer and a surrounding pressure of an atmosphere surrounding the second wafer.

Example 6. The method of one of examples 1 to 5, where the releasing the second set of chucking zones includes releasing chucking zones of the second set of checking zones using a release sequence to control a propagation rate of a bond front.

Example 7. The method of one of examples 1 to 6, where the first wafer holder includes a first vacuum chuck, the second wafer holder includes a second vacuum chuck, the plurality of chucking zones includes a plurality of vacuum nozzles, the first set of chucking zones include a first set of vacuum nozzles, and the second set of chucking zones include a second set of vacuum nozzles.

Example 8. The method of one of examples 1 to 7, further including annealing the bonded wafer at an elevated temperature.

Example 9. A striker for bonding wafers includes a first chucking zone, and a second chucking zone.

Example 10. The striker of example 9, where the first chucking zone includes a first vacuum nozzle configured to hold a surface of a wafer by using a first pressure differential between the surface of the wafer and a surrounding pressure of an atmosphere surrounding the wafer, and where the second chucking zone includes a second vacuum nozzle configured to hold the surface of the wafer by using a second pressure differential between the surface of the wafer and the surrounding pressure of the atmosphere surrounding the wafer.

Example 11. The striker of one of examples 9 or 10, where the first chucking zone includes a first electrode configured to push a surface of a wafer, where the second chucking zone includes a second electrode configured to push the surface of the wafer, and where the striker is configured to push the surface of the wafer using an electrostatic repulsive force generated by applying a first voltage to the first electrode and the second electrode, the wafer being charged at a polarity, the first voltage being a same polarity as the wafer.

Example 12. The striker of one of examples 9 to 11, where the first chucking zone includes a first electrode configured to hold a surface of a wafer, where the second chucking zone includes a second electrode configured to hold the surface of the wafer, and where the striker is configured to hold the surface of the wafer using an electrostatic force formed by applying a first voltage to the first electrode and by applying a second voltage to the second electrode.

Example 13. The striker of one of examples 9 to 12, further including an isolation region disposed between the first electrode and the second electrode, the isolation region including insulating material to prevent electric currents between the first electrode and the second electrode, and where the insulating material includes aluminum oxide, aluminum nitride, silicon nitride, silicon carbide, glass ceramic, or polymer.

Example 14. The striker of one of examples 9 to 13, where the second chucking zone concentrically surrounds the first chucking zone.

Example 15. The striker of one of examples 9 to 14, further including additional chucking zones, each including electrodes.

Example 16. The striker of one of examples 9 to 15, where the first chucking zone and the second chucking zone are segmented such that the first chucking zone includes first segments and the second chucking zone includes second segments, each of the first segments and the second segments being separated by an isolation region.

Example 17. The striker of one of examples 9 to 16, where the first electrode and the second electrode include aluminum, copper, tungsten, titanium, doped silicon carbide, doped aluminum nitride, doped aluminum oxide, or a polymer with conductive fibers.

Example 18. A system for bonding wafers includes a bonding chamber including a second wafer holder, a first wafer holder, and a striker, the second wafer holder including a plurality of chucking zones, the striker including a first chucking zone and a second chucking zone. And the system further includes a controller coupled to the bonding chamber, the first wafer holder, the second wafer holder, the striker, and a memory storing instructions to be executed in the controller. The instructions when executed enable the controller to align a first wafer with a second wafer to form a gap separating the first wafer from the second wafer, the first wafer being held with the first wafer holder and the second wafer being held with the second wafer holder, the plurality of chucking zones including a first set of chucking zones and a second set of chucking zones, hold a surface of the second wafer with the striker, the first set of chucking zones being located nearer to the striker than the second set of chucking zones, release the first set of chucking zones of the second wafer holder while holding the second wafer with the striker, after releasing the first set of chucking zones, push the second wafer into the first wafer using the striker while holding the second wafer with the striker, and release the second set of chucking zones of the second wafer holder to form a bonded wafer.

Example 19. The system of example 18, further including a power source electrically coupled to the first chucking zone and the second chucking zone of the striker, where the power source includes a DC power supply or an AC power supply.

Example 20. The system of one of examples 18 or 19, further including additional strikers disposed over various locations of the second wafer in the second wafer holder.

Example 21. The system of one of examples 18 to 20, where the first chucking zone of the striker includes a first electrode, where the second chucking zone of the striker includes a second electrode, and where the striker is configured to hold the surface of the second wafer using an electrostatic force generated by applying a first voltage to the first electrode and a second voltage to the second electrode.

Example 22. The system of one of examples 18 to 21, where the first chucking zone of the striker includes a first vacuum nozzle configured to hold the surface of the second wafer by using a first pressure differential between the surface of the second wafer and a surrounding pressure of an atmosphere surrounding the second wafer, and where the second chucking zone of the striker includes a second vacuum nozzle configured to hold the surface of the second wafer by using a second pressure differential between the surface of the second wafer and the surrounding pressure of the atmosphere surrounding the second wafer.

Example 23. The system of one of examples 18 to 22, where the first wafer holder includes a first vacuum chuck, and where the second wafer holder includes a second vacuum chuck, the plurality of chucking zones including a plurality of vacuum nozzles.

Example 24. The system of one of examples 18 to 23, where the first chucking zone of the striker includes a first electrode configured to push the surface of the second wafer, where the second chucking zone of the striker includes a second electrode configured to push the surface of the second wafer, and where the striker is configured to push the surface of the wafer using an electrostatic repulsive force generated by applying a first voltage to the first electrode and the second electrode, the second wafer being charged at a polarity, the first voltage being a same polarity as the second wafer.

Example 25. The system of one of examples 18 to 24, where the release of the second set of chucking zones includes releasing the second set of chucking zones after pushing the second wafer.

Example 26. The system of one of examples 18 to 25, where the release of the second set of chucking zones includes releasing the second set of chucking zones before pushing the second wafer.

Example 27. The system of one of examples 18 to 26, where the first wafer holder includes a substantially planar surface for holding a wafer.

Example 28. The system of one of examples 18 to 27, where the first wafer holder includes a bowed surface for forming a symmetric stretch in a wafer held by the first wafer holder.

While the inventive aspects are described primarily in the context of semiconductor wafer bonding, it should also be appreciated that these inventive aspects may also apply to other bonding applications. In particular, aspects of this disclosure may similarly apply to glass substrate bonding, display panel manufacturing, microfluidic device assembly, photonic device fabrication, and medical device manufacturing where precise control of bonding surfaces and minimized distortion are desired.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, embodiments may comprise combinations of embodiments discussed in FIGS. 1-4, and 7. It is therefore intended that the appended claims encompass any such modifications or embodiments.

What is claimed is:

1. A method for bonding wafers, the method comprising:
aligning a first wafer with a second wafer to form a gap separating the first wafer from the second wafer, the first wafer being held with a first wafer holder and the second wafer being held with a second wafer holder, the second wafer holder comprising a plurality of chucking zones, the plurality of chucking zones comprising a first set of chucking zones and a second set of chucking zones;
holding a surface of the second wafer with a striker, the first set of chucking zones being located nearer to the striker than the second set of chucking zones;
releasing the first set of chucking zones while holding the second wafer with the striker;
after releasing the first set of chucking zones, pushing the second wafer into the first wafer using the striker while holding the second wafer with the striker; and
releasing the second set of chucking zones to form a bonded wafer.

2. The method of claim 1, wherein the releasing the second set of chucking zones comprises releasing the second set of chucking zones after pushing the second wafer, and wherein the releasing the second set of chucking zones comprises releasing chucking zones of the second set of checking zones using a release sequence to control a propagation rate of a bond front.

3. The method of claim 1, wherein the releasing the second set of chucking zones comprises releasing the second set of chucking zones before pushing the second wafer, and wherein the releasing the second set of chucking zones comprises releasing chucking zones of the second set of checking zones using a release sequence to control a propagation rate of a bond front.

4. The method of claim 1, wherein the striker comprises a first electrode and a second electrode, the first electrode and the second electrode configured to hold the surface of the second wafer using an electrostatic force generated by applying a first voltage to the first electrode and a second voltage to the second electrode, the first voltage comprising a first polarity, the second voltage comprising a second polarity, the first polarity being opposite the second polarity.

5. The method of claim 1, wherein the striker comprises a vacuum nozzle, the vacuum nozzle configured to hold the surface of the second wafer using a pressure differential between the surface of the second wafer and a surrounding pressure of an atmosphere surrounding the second wafer.

6. The method of claim 1, wherein the first wafer holder comprises a first vacuum chuck, the second wafer holder comprises a second vacuum chuck, the plurality of chucking zones comprises a plurality of vacuum nozzles, the first set of chucking zones comprise a first set of vacuum nozzles, and the second set of chucking zones comprise a second set of vacuum nozzles.

7. A striker for bonding wafers, the striker comprising:
a first chucking zone; and
a second chucking zone.

8. The striker of claim 7, wherein the first chucking zone comprises a first vacuum nozzle configured to hold a surface of a wafer by using a first pressure differential between the surface of the wafer and a surrounding pressure of an atmosphere surrounding the wafer, and wherein the second chucking zone comprises a second vacuum nozzle configured to hold the surface of the wafer by using a second pressure differential between the surface of the wafer and the surrounding pressure of the atmosphere surrounding the wafer.

9. The striker of claim 7, wherein the first chucking zone comprises a first electrode configured to push a surface of a wafer, wherein the second chucking zone comprises a second electrode configured to push the surface of the wafer, and wherein the striker is configured to push the surface of the wafer using an electrostatic repulsive force generated by applying a first voltage to the first electrode and the second electrode, the wafer being charged at a polarity, the first voltage being a same polarity as the wafer.

10. The striker of claim 7, wherein the first chucking zone comprises a first electrode configured to hold a surface of a wafer, wherein the second chucking zone comprises a second electrode configured to hold the surface of the wafer, wherein the striker is configured to hold the surface of the wafer using an electrostatic force formed by applying a first voltage to the first electrode and by applying a second voltage to the second electrode, and wherein the first electrode and the second electrode comprise aluminum, copper, tungsten, titanium, doped silicon carbide, doped aluminum nitride, doped aluminum oxide, or a polymer with conductive fibers.

11. The striker of claim 10, further comprising an isolation region disposed between the first electrode and the second electrode, the isolation region comprising insulating material to prevent electric currents between the first electrode and the second electrode, and wherein the insulating material comprises aluminum oxide, aluminum nitride, silicon nitride, silicon carbide, glass ceramic, or polymer.

12. The striker of claim 10, further comprising additional chucking zones comprising electrodes, and wherein the second chucking zone concentrically surrounds the first chucking zone.

13. The striker of claim 10, wherein the first chucking zone and the second chucking zone are segmented such that the first chucking zone comprises first segments and the second chucking zone comprises second segments, each of the first segments and the second segments being separated by an isolation region.

14. A system for bonding wafers, the system comprising:
a bonding chamber comprising a second wafer holder, a first wafer holder, and a striker, the second wafer holder comprising a plurality of chucking zones, the striker comprising a first chucking zone and a second chucking zone; and
a controller coupled to the bonding chamber, the first wafer holder, the second wafer holder, the striker, and a memory storing instructions to be executed in the controller, the instructions when executed enable the controller to:
align a first wafer with a second wafer to form a gap separating the first wafer from the second wafer, the first wafer being held with the first wafer holder and the second wafer being held with the second wafer holder, the plurality of chucking zones comprising a first set of chucking zones and a second set of chucking zones,
hold a surface of the second wafer with the striker, the first set of chucking zones being located nearer to the striker than the second set of chucking zones,
release the first set of chucking zones of the second wafer holder while holding the second wafer with the striker,
after releasing the first set of chucking zones, push the second wafer into the first wafer using the striker while holding the second wafer with the striker, and
release the second set of chucking zones of the second wafer holder to form a bonded wafer.

15. The system of claim 14, further comprising a power source electrically coupled to the first chucking zone and the second chucking zone of the striker, wherein the power source comprises a DC power supply or an AC power supply, wherein the first chucking zone of the striker comprises a first electrode, wherein the second chucking zone of the striker comprises a second electrode, and wherein the striker is configured to hold the surface of the second wafer using an electrostatic force generated by applying a first voltage to the first electrode and a second voltage to the second electrode.

16. The system of claim 14, wherein the first chucking zone of the striker comprises a first vacuum nozzle configured to hold the surface of the second wafer by using a first pressure differential between the surface of the second wafer and a surrounding pressure of an atmosphere surrounding the second wafer, and wherein the second chucking zone of the striker comprises a second vacuum nozzle configured to hold the surface of the second wafer by using a second pressure differential between the surface of the second wafer and the surrounding pressure of the atmosphere surrounding the second wafer.

17. The system of claim 14, wherein the first wafer holder comprises a first vacuum chuck, and wherein the second wafer holder comprises a second vacuum chuck, the plurality of chucking zones comprising a plurality of vacuum nozzles.

18. The system of claim 14, further comprising a power source electrically coupled to the first chucking zone and the second chucking zone of the striker, wherein the power source comprises a DC power supply or an AC power supply, wherein the first chucking zone of the striker comprises a first electrode configured to push the surface of the second wafer, wherein the second chucking zone of the striker comprises a second electrode configured to push the surface of the second wafer, and wherein the striker is configured to push the surface of the wafer using an electrostatic repulsive force generated by applying a first voltage to the first electrode and the second electrode, the second wafer being charged at a polarity, the first voltage being a same polarity as the second wafer.

19. The system of claim 14, wherein the release of the second set of chucking zones comprises releasing the second set of chucking zones after pushing the second wafer, or wherein the release of the second set of chucking zones comprises releasing the second set of chucking zones before pushing the second wafer.

20. The system of claim 14, wherein the first wafer holder comprises either a substantially planar surface for holding a wafer or a bowed surface for forming a symmetric stretch in the wafer held by the first wafer holder.
